(19) United States
(12) Patent Application Publication
(10) Pub. No.: US 2006/0027259 A1
(43) Pub. Date: Feb. 9, 2006

(54) Infrared sensor

(75) Inventor: Kazuaki Watanabe, Nagoya-city (JP)

Correspondence Address: POSZ LAW GROUP, PLC, 12040 SOUTH LAKES DRIVE, SUITE 101, RESTON, VA, 20191, US

(73) Assignee: DENSO CORPORATION

(21) Appl. No.: 11/188,863

(22) Filed: Jul. 26, 2005

(30) Foreign Application Priority Data
Aug. 4, 2004 (JP) 2004-227828

(51) Int. Cl. H01L 35/28

(52) U.S. Cl. 136/224; 136/212

(57) ABSTRACT

An infrared sensor including a substrate, a membrane as a thin wall portion formed in this substrate, thermocouples in which a warm contact portion is formed on said membrane and a cold contact portion is formed outside said membrane on said substrate and an infrared ray absorbing film formed on said membrane so as to cover said warm contact portion in said thermocouples. Electromotive force of said thermocouples is changed by a temperature difference caused between said warm contact portion and said cold contact portion in said thermocouples at a receiving time of an infrared ray, and the infrared ray is detected on the basis of the changed electromotive force. A temperature sensing element using the same material as a material constituting said thermocouples and detecting temperature by utilizing the temperature depending property of electric resistance of this material is formed in said substrate.

### CROSS REFERENCE TO RELATED APPLICATION

This application is based upon, claims the benefit of priority of, and incorporates by reference the contents of Japanese Patent Application No. 2004-227828 filed on Aug. 4, 2004.

### FIELD OF THE INVENTION

The present invention relates to an infrared sensor of a thermopile type for detecting an infrared ray on the basis of a change in electromotive force generated in a thermocouple by a temperature difference caused at a receiving time of the infrared ray.

### BACKGROUND OF THE INVENTION

A thermopile type infrared sensor generally has a membrane as a thin wall portion formed in a substrate, a thermocouple in which a warm contact portion is formed on the membrane and a cold contact portion is formed outside the membrane on the substrate, and an infrared ray absorbing film formed on the membrane so as to cover the warm contact portion in the thermocouple.

When the infrared ray is received, the electromotive force of the thermocouple is changed by the temperature difference caused between the warm contact portion and the cold contact portion in the thermocouple. The infrared ray is detected on the basis of the changed electromotive force.

Thus, the infrared sensor of the thermopile type is a sensor utilizing the Seebeck effect, but has the defect that no temperature of the sensor itself is known. It is generally known to simultaneously use a temperature sensing element for detecting temperature to compensate for this defect.

Namely, as mentioned above, the temperature difference can be detected by the infrared sensor itself. The temperature of the infrared sensor itself is detected by the temperature sensing element, and the temperature of a measured object is calculated on the basis of this temperature and the above temperature difference.

Conventionally, the relationship between resistance value and temperature of, for example, a thermistor as the temperature sensing element is used. As a forming method of this temperature sensing element, since it is simple to arrange a ceramic thermistor in the vicinity of the infrared sensor (e.g., see patent literature 1), the infrared sensor of the thermopile type also adopts this arrangement in general.
Patent literature 1: JP-A-60-178323

However, even when the temperature sensing element is arranged in the vicinity of the infrared sensor, no temperature sensing element is formed in the infrared sensor itself. Therefore, there are defects in that response is bad and a temperature error is caused, etc. A means for forming a resistance element having the temperature depending property on the infrared sensor is considered to avoid these defects. However, it is necessary to add a separate material and a separate process for this means so that cost is raised.

### SUMMARY OF THE INVENTION

In consideration of the above problems, an object is to be able to precisely detect the temperature of the sensor itself by a cheap construction in the infrared sensor of the thermopile type.

To achieve the above object, as a result of earnest consideration, a property of the infrared sensor of the thermopile type in which a material constituting a thermocouple has the temperature depending property of electric resistance is utilized.

Namely, the first aspect is characterized in an infrared sensor comprising a substrate; a membrane as a thin wall portion formed in this substrate; thermocouples in which a warm contact portion is formed on the membrane and a cold contact portion is formed outside the membrane on the substrate; and an infrared ray absorbing film formed on the membrane so as to cover the warm contact portion in the thermocouples; wherein electromotive force of the thermocouples is changed by a temperature difference caused between the warm contact portion and the cold contact portion in the thermocouples at a receiving time of an infrared ray, and the infrared ray is detected on the basis of the changed electromotive force; and a temperature sensing element using the same material as a material constituting the thermocouples and detecting temperature by utilizing the temperature depending property of electric resistance of this material is formed in the substrate.

In accordance with this construction, since the temperature sensing element is formed in the substrate itself constituting the infrared sensor, i.e., in the infrared sensor itself, the temperature detection of the infrared sensor itself can be precisely performed.

Further, since the temperature sensing element is formed by using the same material as the material constituting the thermocouples, the temperature sensing element can be formed simultaneously with the thermocouples in a forming process of the thermocouples in a manufacture process. Further, it is not necessary to use a separate material for the temperature sensing element.

Accordingly, the temperature of the sensor itself can be precisely detected by a cheap construction in the infrared sensor of the thermopile type.

Here, the second aspect is characterized in that at least one portion of the thermocouples is constructed as the temperature sensing element in the infrared sensor according to the first aspect.

Thus, since at least one portion of the thermocouples is constructed as the temperature sensing element, it is possible to set a construction in which the thermocouples are also used as the temperature sensing element.

### BRIEF DESCRIPTION OF THE DRAWINGS

The above and other objects, features and advantages of the present invention will become more apparent from the following detailed description made with reference to the accompanying drawings. In the drawings:

FIG. 1 is a schematic plan view of an infrared sensor of a thermopile type utilizing electromotive force of plural thermocouples in accordance with a first embodiment;

FIG. 2 is a typical sectional view along section II-II within FIG. 1;

FIG. 3 is a schematic sectional view showing the vicinity of the thermocouple and a temperature sensing element in the infrared sensor of the above first embodiment;

FIG. 4 is a schematic sectional view along the longitudinal direction of the temperature sensing element in the infrared sensor of the above first embodiment mode;

FIG. 5 is a view showing the relation of temperature and resistance with respect to a material constituting the thermocouple;

FIG. 6 is a schematic plan view of an infrared sensor of the thermopile type utilizing the electromotive force of plural thermocouples in accordance with a second embodiment;

FIG. 7 is a schematic plan view of an infrared sensor of the thermopile type utilizing the electromotive force of plural thermocouples in accordance with a third embodiment mode.

### DESCRIPTION OF THE PREFERRED EMBODIMENTS

The embodiment will be explained on the basis of the drawings. In the following respective mutual embodiment modes, the same reference numerals are designated in portions equal or equivalent to each other within the drawings to simplify the explanation.

### First Embodiment Mode

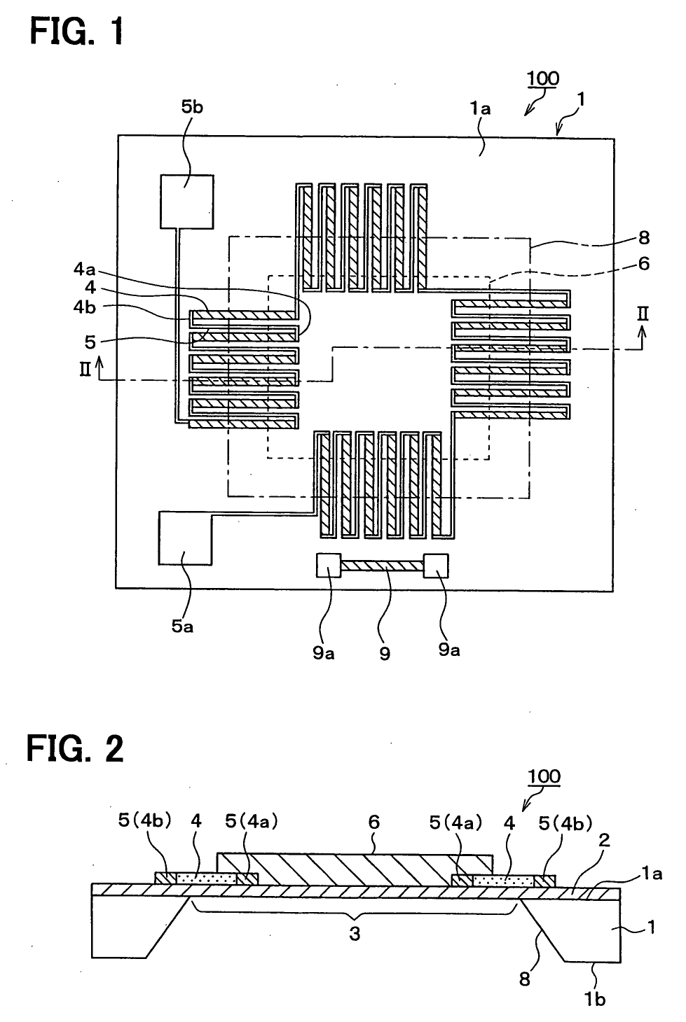

FIG. 1 is a view showing the schematic planar construction of an infrared sensor 100 of a thermopile type utilizing electromotive force of plural thermocouples in accordance with a first embodiment. FIG. 2 is a typical sectional view along section II-II within FIG. 1.

Hatching within FIG. 1 is performed to easily discriminate each portion and does not show a section. Further, the thickness of each film, the size of wiring, etc. are shown so as to be slightly different in FIGS. 1 and 2.

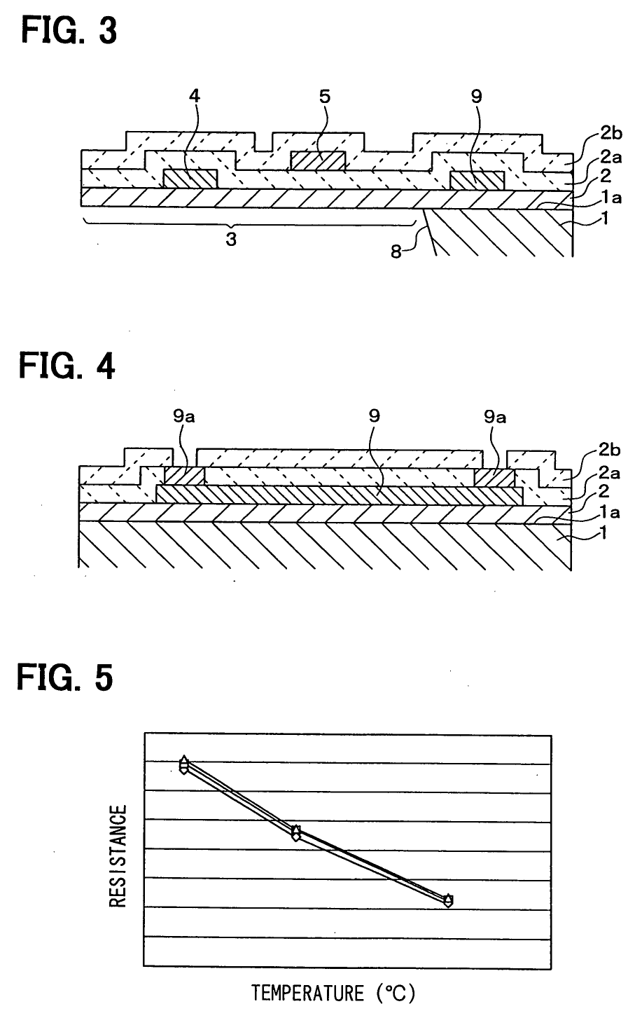

FIG. 3 is a view showing a schematic sectional construction of thermocouples 4, 5 and a temperature sensing element 9 in this infrared sensor 100. FIG. 4 is a view showing a schematic sectional construction along the longitudinal direction of the temperature sensing element 9 in this infrared sensor 100.

This infrared sensor 100 has a silicon substrate (a silicon chip having a rectangular plate shape in this example) 1 having planes (100) and (110) in the planar azimuth of a principal plane as a substrate 1. An element portion required in sensing is formed by laminating various kinds of wirings, films, etc. on the surface 1a side of this silicon substrate 1. Further, a cavity portion 8 is formed by performing wet etching from the rear face 1b side of the silicon substrate 1. In FIG. 1, the outer shape of the cavity portion 8 is shown by a one-dotted chain line.

As shown in FIGS. 2 to 4, an insulating thin film 2 constructed by a silicon nitride film, a silicon oxide film, etc. formed by the CVD method, the sputtering method, the evaporation method, etc. is formed approximately in an entire area including the upper portion of the cavity portion 8 on the surface 1a of this silicon substrate 1.

Here, when the silicon substrate 1 except for the cavity portion 8 is set to a thick wall portion (e.g., about 400 μm in thickness), a portion of the insulating thin film 2 located on the cavity portion 8 on the surface 1a of the silicon substrate 1 is constructed as a thin wall portion (e.g., about 2 μm in thickness), i.e., a membrane 3.

Plural polysilicon wirings (shown by slanting line hatching within FIG. 1) 4 constructed by polysilicon formed by the CVD method, etc. and plural aluminum wirings 5 constructed by aluminum formed by the sputtering method, the evaporation method, etc. are respectively formed in a radiating direction over the thick wall portion of the silicon substrate 1 outside the membrane 3 from the central portion of the membrane 3 on the insulating thin film 2.

Here, as shown in FIG. 3, an interlayer insulating film 2a constructed by a silicon nitride film, a silicon oxide film, etc. formed by the CVD method, the sputtering method, the evaporation method, etc. is formed on the polysilicon wiring 4 and the insulating thin film 2 in which no polysilicon wiring 4 is formed. The aluminum wiring 5 is formed on this interlayer insulating film 2a.

The aluminum wiring 5 connects end portions of each polysilicon wiring 4 through an opening portion (contact hole) formed in this interlayer insulating film 2a although this connection is not illustrated in the drawings.

Thus, the plural polysilicon wirings 4 and the plural aluminum wirings 5 are connected in series and construct the thermocouples 4, 5 of the infrared sensor 100. As shown in FIG. 1, these thermocouples 4, 5 have a folded-back shape: folded back plural times.

Each of these plural folded-back portions 4a, 4b becomes a joining portion of both the wirings 4, 5, and electromotive force is generated by the Seebeck effect in the mutual joining portion of these different kinds of materials.

As shown in FIG. 1, both aluminum pads 5a, 5b for electric connection with an external circuit by a bonding wire, etc. are conducted to the aluminum wirings 5 of both end portions of the thermocouples 4, 5.

The folded-back portion 4a located on the membrane 3 becomes a warm contact portion, and the folded-back portion 4b located in the thick wall portion of the silicon substrate 1 outside the membrane 3 becomes a cold contact portion. The voltages of the thermocouples 4, 5 based on the temperature difference between both the contact portions 4a and 4b are outputted between both the above aluminum pads 5a and 5b.

Namely, two wirings constructed by the polysilicon wiring 4 and the aluminum wiring 5 adjacently connected in series are constructed as one thermocouple. In each of the thermocouples 4, 5, the warm contact portion 4a is formed on the membrane 3, and the cold contact portion 4b is formed outside (thick wall portion) the membrane 3 on the silicon substrate 1. In this example, a plurality of such thermocouples 4, 5 are connected in series to increase their outputs.

Further, as shown in FIG. 3, a protecting film 2b constructed by a silicon nitride film, a silicon oxide film, etc. formed by the CVD method, the sputtering method, the evaporation method, etc. is formed on the aluminum wiring 5 and the interlayer insulating film 2a in which no aluminum wiring 5 is formed.

An infrared ray absorbing film 6 is formed on the protecting film 2b in the central portion on the membrane 3 so as to cover the folded-back portion 4a as the above warm contact portion. Here, in this example, the infrared ray absorbing film 6 is separated from an outer circumferential end portion of the membrane 3 and is located inside the membrane 3.

In this infrared ray absorbing film 6, carbon (C) is included in polyester resin, and is coated, burned and solidified by a printing method of screen printing, etc. This infrared ray absorbing film 6 is used to efficiently raise the temperature of the warm contact portion by absorbing an infrared ray. In FIG. 1, the outer shape of the infrared ray absorbing film 6 is shown by a broken line.

In the infrared sensor 100 having such a construction, the warm contact portion 4a located on the membrane 3 having small heat capacity has a heat sinking property smaller than that of the cold contact portion 4b located on the thick wall portion having large heat capacity. Namely, the thick wall portion of the silicon substrate 1 fulfills the function of a heat sink.

Therefore, when the infrared ray is irradiated from a human body, etc. as a measured object and is received on the surface 1a side of the silicon substrate 1, the infrared ray is absorbed into the infrared ray absorbing film 6 and a temperature rise is caused. As its result, the temperature of the folded-back portion (warm contact portion) 4a covered with the infrared ray absorbing film 6 is raised.

Temperature rise is almost never caused in the folded-back portion (cold contact portion) 4b located on the thick wall portion of the silicon substrate 1 since the silicon substrate 1 becomes the heat sink. As a result, the warm contact portion 4a becomes a temperature higher than that of the cold contact portion 4b and a temperature difference is caused between both the contact portions 4a and 4b. Therefore, electromotive force is generated by the Seebeck effect.

A sum total Vout (a thermopile output and a sensor output) of the voltages of the plural thermocouples 4, 5 according to the temperature difference between both the contact portions 4a and 4b is outputted from both the aluminum pads (sensor output terminals) 5a and 5b to the above external circuit, etc. so that the infrared ray can be detected.

In such an infrared sensor 100, as shown in FIGS. 3 and 4, this embodiment mode adopts an independent construction in which a temperature sensing element 9 using the same material as a material constituting the thermocouples 4, 5 and detecting temperature by utilizing the temperature depending property of electric resistance of this material is formed in the substrate 1.

Here, the temperature sensing element 9 is constructed by the same material as the polysilicon wiring 4 among the thermocouples 4, 5, i.e., a polysilicon material in the thick wall portion of the silicon substrate 1. The temperature sensing element 9 is formed by the CVD method, etc. on the same plane as the polysilicon wiring 4 on the insulating thin film 2. In FIG. 1, similar to the polysilicon wiring 4, this temperature sensing element 9 is shown by slanting line hatching.

As shown in FIG. 4, the temperature sensing element 9 is covered with the interlayer insulating film 2a and the protecting film 2b. However, in both end portions of the temperature sensing element 9, an opening portion (contact hole) is formed in the interlayer insulating film 2a and the protecting film 2b.

As shown in FIG. 4, pads 9a, 9a for the temperature sensing element constructed by aluminum, etc. are formed in this opening portion. Each of these pads 9a, 9a and the temperature sensing element 9 are electrically connected to each other. A bonding wire, etc. are connected to each of the pads 9a, 9a, and the temperature sensing element 9 can be conducted to an external circuit.

As a modified example of this embodiment mode, the temperature sensing element may also be constructed by the same material as the aluminum wiring 5 among the thermocouples 4, 5, i.e., aluminum although this construction is not illustrated in the drawings.

In this case, the temperature sensing element is formed by the sputtering method, the evaporation method, etc. on the same plane as the aluminum wiring 5 on the interlayer insulating film 2a. This temperature sensing element constructed by aluminum can be set to be electrically connected to the external circuit through the contact hole formed in the protecting film 2b.

The above infrared sensor 100 can be manufactured by using a well-known semiconductor manufacture technique with respect to a silicon wafer finally divisionally cut into a chip unit and formed as the above silicon substrate 1.

Concretely, the insulating thin film 2 constructed by a silicon nitride film, a silicon oxide film, etc. is first formed by the CVD method, the sputtering method, the evaporation method, etc. with respect to each chip forming area of the above silicon wafer surface.

The polysilicon wiring 4 and the temperature sensing element 9 constructed by polysilicon are formed on this insulating thin film 2 by using a film forming technique such as the CVD method, etc. and a patterning technique using the photolithograph method, etc. Namely, in this embodiment mode, since the temperature sensing element 9 is formed by the same material as the thermocouples 4, 5, the polysilicon wiring 4 and the temperature sensing element 9 as the same material can be simultaneously formed in the same process.

Next, the interlayer insulating film 2a constructed by a silicon nitride film, a silicon oxide film, etc. is formed on the polysilicon wiring 4 and the temperature sensing element 9 by the CVD method, the sputtering method, the evaporation method, etc. The aluminum wiring 5 constructed by aluminum is formed on the interlayer insulating film 2a by using the film forming technique such as the sputtering method, the evaporation method, etc., and the pattering technique using the photolithograph method, etc.

As described in the above modified example, when the temperature sensing element is constructed by the same material as the aluminum wiring 5 among the thermocouples 4, 5, i.e., aluminum, the aluminum wiring 5 and the temperature sensing element 9 as the same material can be simultaneously formed on the interlayer insulating film 2a.

Next, the protecting film 2b constructed by a silicon nitride film, a silicon oxide film, etc. is formed on the aluminum wiring 5 and the temperature sensing element 9 by the CVD method, the sputtering method, the evaporation method, etc. Etching is then performed with respect to the interlayer insulating film 2a and the protecting film 2b, and the above opening portion for forming the pads 9a, 9a for the temperature sensing element is formed.

The pads 9a, 9a for the above temperature sensing element constructed by aluminum, etc. are formed by the sputtering method, the evaporation method, etc. with respect to this opening portion.

Thereafter, the cavity portion 8 is formed and the membrane 3 is formed by performing wet etching from the rear face side of the above silicon wafer. Thereafter, the infrared ray absorbing film 6 is formed by a printing method of screen printing, etc., and the above silicon wafer is divisionally cut into a chip unit by performing dicing cut, etc. Thus, the above infrared sensor 100 is completed.

In such an infrared sensor 100, the material constituting the thermocouples 4, 5 in the temperature sensing element 9 has the temperature depending property of electric resistance. For example, FIG. 5 is a view showing results in which the relation of temperature and resistance is examined when the material constituting the thermocouples 4, 5 is set to n=3.

As shown in FIG. 5, in the temperature sensing element 9, the electric resistance is reduced as temperature is lowered. Namely, the resistance value of the temperature sensing element 9 is changed as the temperature of the infrared sensor 100 itself is changed.

This resistance change of the temperature sensing element 9 is outputted from the pads 9a, 9a for the temperature sensing element to the external circuit, etc. Therefore, the temperature of the infrared sensor 100 itself can be detected on the basis of this resistance change of the temperature sensing element 9.

The temperature of a measured object can be calculated on the basis of the temperature of the infrared sensor 100 itself calculated from this temperature sensing element 9 and the temperature difference detected from the above infrared sensor 100.

This embodiment mode provides an infrared sensor 100 comprising a substrate 1; a membrane 3 as a thin wall portion formed in this substrate 1; thermocouples 4, 5 in which a warm contact portion 4a is formed on the membrane 3 and a cold contact portion 4b is formed outside the membrane 3 on the substrate 1; and an infrared ray absorbing film 6 formed on the membrane 3 so as to cover the warm contact portion 4a in the thermocouples 4, 5; wherein electromotive force of the thermocouples 4, 5 is changed by a temperature difference caused between the warm contact portion 4a and the cold contact portion 4b in the thermocouples 4, 5 at a receiving time of an infrared ray, and the infrared ray is detected on the basis of the changed electromotive force; and a temperature sensing element 9 using the same material as a material constituting the thermocouples 4, 5 and detecting temperature by utilizing the temperature depending property of electric resistance of this material is formed in the substrate 1.

In accordance with this infrared sensor 100, since the temperature sensing element 9 is formed in the substrate 1 itself constituting the infrared sensor 100, i.e., the infrared sensor 100 itself, the temperature detection of the infrared sensor 100 itself can be precisely performed.

Further, since the temperature sensing element 9 is formed by using the same material as the material constituting the thermocouples 4, 5, the temperature sensing element 9 can be formed simultaneously with the thermocouples 4, 5 in a forming process of the thermocouples in a manufacture process. Further, it is not necessary to use a separate material for the temperature sensing element 9.

Accordingly, in accordance with this embodiment mode, the temperature of the sensor itself can be precisely detected by a low cost construction in the infrared sensor of the thermopile type.

### Second Embodiment Mode

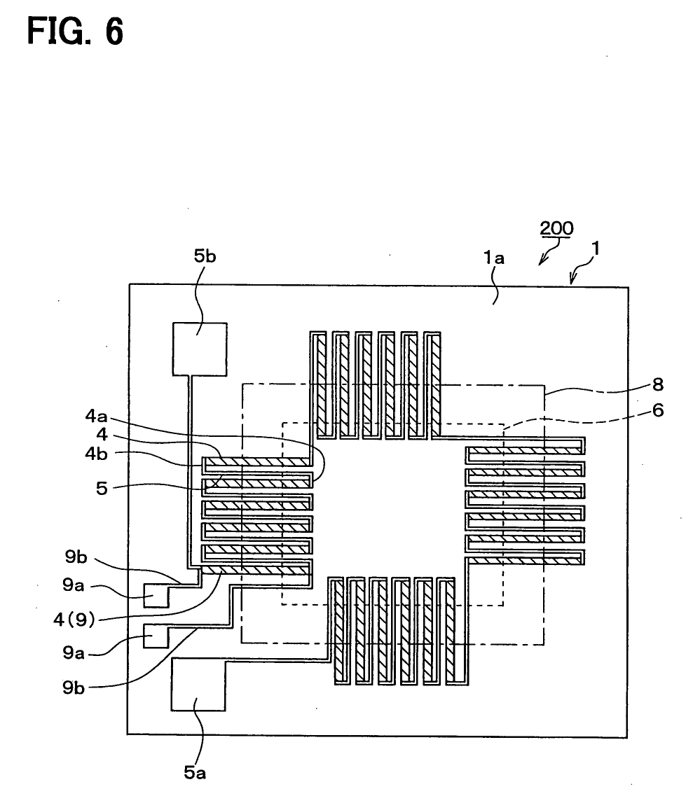

FIG. 6 is a schematic plan view of an infrared sensor 200 of the thermopile type utilizing the electromotive force of plural thermocouples in accordance with a second embodiment. The different points from the above first embodiment mode will be centrally described.

In the above first embodiment mode, the thermocouples 4, 5 and the temperature sensing element 9 constructed by the same material are arranged in parts different from each other in the substrate 1 constituting the infrared sensor, i.e., the silicon substrate 1.

In contrast to this, in the infrared sensor 200 of this embodiment mode, as shown in FIG. 6, one portion of the thermocouples 4, 5 is constructed as the temperature sensing element 9. It is possible to set a construction in which one portion of the thermocouples 4, 5 is also used as the temperature sensing element 9 by constructing one portion of the thermocouples 4, 5 as the temperature sensing element 9.

In the example shown in FIG. 6, wirings 9b, 9b constructed by aluminum, etc. are electrically connected to pads 9a, 9a for the temperature sensing element by pulling the wirings 9b, 9b out of both ends of one portion of the polysilicon wiring 4. Similar to this construction, one portion of the aluminum wiring 5 may be also constructed as the temperature sensing element 9.

In this embodiment mode, since the temperature sensing element 9 is formed in the infrared sensor 200 itself, the temperature detection of the infrared sensor 200 itself can be precisely performed. Further, the temperature sensing element 9 can be formed simultaneously with the thermocouples 4, 5 since the temperature sensing element 9 is also used as the thermocouples 4, 5 and is formed by using the same material as the thermocouples 4, 5.

Accordingly, in this embodiment mode, the temperature of the sensor itself can be also precisely detected by a cheap construction in the infrared sensor of the thermopile type.

### Third Embodiment Mode

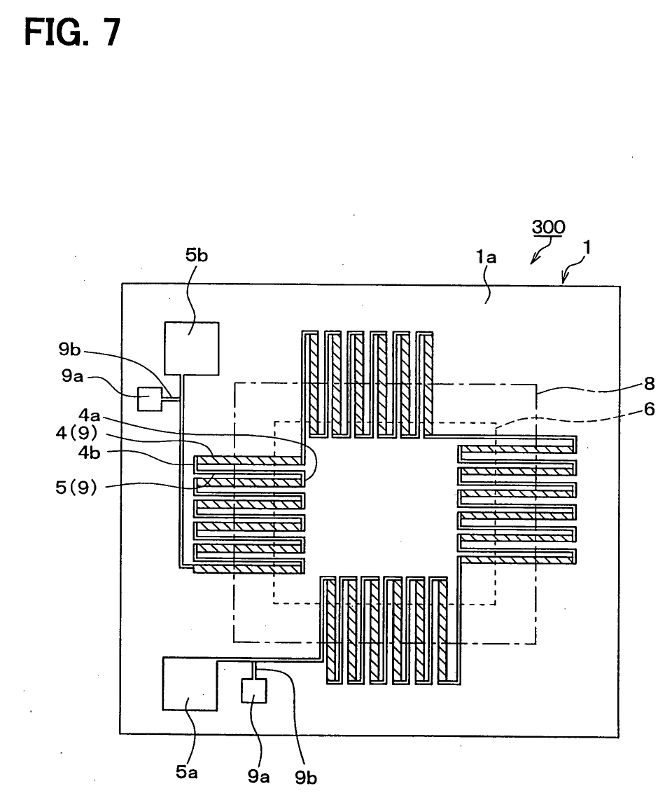

FIG. 7 is a schematic plan view of an infrared sensor 300 of the thermopile type utilizing the electromotive force of plural thermocouples in accordance with a third embodiment mode. The different points from the above embodiment modes will be centrally described.

As shown in FIG. 7, all portions of the thermocouples 4, 5 are constructed as the temperature sensing element 9 in the infrared sensor 300 of this embodiment mode. Namely, it is possible to set a construction in which the thermocouples 4, 5 are also used as the temperature sensing element 9 by constructing all the portions of the thermocouples 4, 5 as the temperature sensing element 9.

In the example shown in FIG. 7, wirings 9b, 9b constructed by aluminum, etc. are electrically connected to pads 9a, 9a for the temperature sensing element by pulling the wirings 9b, 9b out of the aluminum wirings 5 of both end portions of the thermocouples 4, 5.

Further, in the case of this embodiment mode, the aluminum pads 5a, 5b of the thermocouples 4, 5 and the pads 9a, 9a for the temperature sensing element are not separately arranged, but may be integrated. In this case, an adjustment may be made by an external circuit, etc. so as to switch a voltage output and a resistance output of the thermocouples 4, 5.

In this embodiment mode, the temperature detection of the infrared sensor 300 itself can be precisely performed since the temperature sensing element 9 is formed in the infrared sensor 300 itself. Further, since the temperature sensing element 9 is also used as the thermocouples 4, 5 and is formed by using the same material as the thermocouples 4, 5, the temperature sensing element 9 can be formed simultaneously with the thermocouples 4, 5.

Accordingly, in this embodiment mode, the temperature of the sensor itself can be precisely detected by a cheap construction in the infrared sensor of the thermopile type.

### Other Embodiment Modes

The constructional material of the thermocouples 4, 5 is not limited to polysilicon and aluminum mentioned above, but may be set to a material able to be used in the infrared sensor of the thermopile type. This is because such a material has the temperature depending property of electric resistance.

Further, plural temperature sensing elements may be also arranged with respect to one infrared sensor, i.e., on one substrate.

For example, plural temperature sensing elements constructed by the same material as the polysilicon wiring 4 among the above thermocouples 4, 5 may be arranged on the same plane as the polysilicon wiring 4 on the insulating thin film 2. Plural temperature sensing elements constructed by the same material as the aluminum wiring 5 may be also arranged on the same plane as the aluminum wiring 5 on the interlayer insulating film 2a.

Further, the temperature sensing element constructed by the same material as the polysilicon wiring 4 among the above thermocouples 4, 5 is arranged on the same plane as the polysilicon wiring 4 on the insulating thin film 2, and the temperature sensing element constructed by the same material as the aluminum wiring 5 is arranged on the same plane as the aluminum wiring 5 on the interlayer insulating film 2a. Thus, it is also possible to set a construction for arranging the plural temperature sensing elements.

As shown in each figure, the infrared sensor in each of the above embodiment modes is an infrared sensor of the thermopile type of a rear face processing type in which the membrane 3 is formed by forming the cavity portion 8 by performing the wet etching from the rear face 1b side of the silicon substrate 1.

For example, the infrared sensor of the thermopile type of a surface processing type for forming the membrane by utilizing trench etching and sacrifice layer etching from the surface of the silicon substrate may be also used as the infrared sensor applied to the present invention in addition to the infrared sensor of the above rear face processing type.

In short, the infrared sensor of the thermopile type is generally composed of a membrane as a thin wall portion formed in a substrate; thermocouples in which a warm contact portion is formed on the membrane and a cold contact portion is formed outside the membrane on the substrate; and an infrared ray absorbing film formed on the membrane so as to cover the warm contact portion in the thermocouples; wherein a temperature sensing element using the same material as a material constituting the thermocouples and detecting temperature by utilizing the temperature depending property of electric resistance of this material is formed with respect to the substrate. The other portions can be suitably designed and changed.

What is claimed is:

1. An infrared sensor comprising:
a substrate;
a membrane as a thin wall portion formed in this substrate;
thermocouples in which a warm contact portion is formed on said membrane and a cold contact portion is formed outside said membrane on said substrate; and
an infrared ray absorbing film formed on said membrane so as to cover said warm contact portion in said thermocouples;
wherein electromotive force of said thermocouples is changed by a temperature difference caused between said warm contact portion and said cold contact portion in said thermocouples at a receiving time of an infrared ray, and the infrared ray is detected on the basis of the changed electromotive force; and
a temperature sensing element using the same material as a material constituting said thermocouples and detecting temperature by utilizing the temperature depending property of electric resistance of this material is formed in said substrate.

2. The infrared sensor according to claim 1, wherein at least one portion of said thermocouples is constructed as said temperature sensing element.
